(19) United States
(12) Patent Application Publication
(10) Pub. No.: US 2009/0151623 A1
(43) Pub. Date: Jun. 18, 2009

(54) FORMATION AND APPLICATIONS OF HIGH-QUALITY EPITAXIAL FILMS

(75) Inventor: Darwin Gene Enicks, Colorado Springs, CO (US)

Correspondence Address: SCHWEGMAN, LUNDBERG & WOESSNER / ATMEL, P.O. BOX 2938, MINNEAPOLIS, MN, 55402, US

(73) Assignee: ATMEL CORPORATION, San Jose, CA (US)

(21) Appl. No.: 11/955,328

(22) Filed: Dec. 12, 2007

(51) Int. Cl. C30B 25/08; H01L 21/20

(52) U.S. Cl. 117/94; 438/503; 257/E21.002

(57) ABSTRACT

A method and system for forming high-quality epitaxial films. In one embodiment, the method includes cleaning a substrate, reducing adsorbed moisture on the substrate in a predefined temperature and predefined oxygen level atmosphere, and removing native oxide from the substrate. The method also includes prebaking the substrate and growing an epitaxial layer doped with an impurity, wherein the impurity has a nano-impurity profile.

### FIELD OF THE INVENTION

The present invention relates to semiconductor device fabrication, and more particularly to a method and system for forming high-quality epitaxial films.

### BACKGROUND OF THE INVENTION

In semiconductor device manufacturing, it is desirable to form thinner epitaxial films due to semiconductor devices becoming smaller in dimension. One way to achieve thinner epitaxial films is to form them in lower temperatures. However, achieving low temperature growth of high-quality epitaxial films may be very difficult due to a number of processing concerns and requirements. For example, low pressure chemical vapor deposition (LPCVD) processes tend to very readily incorporate contaminants such as oxygen. Oxygen can degrade interface quality, leading to defective epitaxial layers, or growth of a poly or amorphous film instead of true epitaxy. Oxygen will also degrade the electrical performance of the film due to a reduction in hole mobility in doped layers, and alter the diffusion of dopants such as boron, phosphorous, and arsenic, to name only a few. These issues are also present with other types of processes such as ultra-high vacuum chemical vapor deposition (UHVCVD) and molecular beam epitaxy (MBE).

The growth of high-quality films such as silicon (Si), silicon germanium (SiGe), silicon germanium carbon (SiGeC), silicon carbide (SiC), germanium (Ge), and germanium carbide (GeC) films doped with impurities requires careful control of mass flow controllers and thermal conditions within the reactor used to form the films while controlling contamination. Contamination control requires robust systems and methods for removing oxygen from reactor components and for cleaning the substrate surface so that low temperature LPCVD (or UHVCVD, MBE) can be carried out successfully.

Accordingly, what is needed is mechanisms to solve the above deficiencies.

### SUMMARY OF THE INVENTION

A method and system for forming high-quality epitaxial films is disclosed. In one embodiment, the method includes cleaning a substrate and reducing adsorbed moisture on the substrate in a predefined temperature and predefined oxygen level atmosphere. The method also includes prebaking the substrate to remove native oxide and growing an epitaxial layer doped with an impurity, wherein the impurity has a nano-impurity profile. According to the method and system disclosed herein, high-quality epitaxial films are formed having ultra thin, nano-impurity profiles.

### BRIEF DESCRIPTION OF THE DRAWINGS

FIG. 1 is a block diagram of a computer system that may be used with a chemical vapor deposition reactor in accordance with one embodiment of the present invention.

FIG. 2 is a top-view block diagram of a low-pressure chemical vapor deposition (LPCVD) reactor, which may be used to implement the chemical vapor deposition reactor of FIG. 1, in accordance with one embodiment of the present invention.

FIG. 3 is a side-view block diagram of a process chamber, which may be used to implement one of the process chambers of FIG. 2, in accordance with one embodiment of the present invention.

FIG. 4 is a cross-section diagram of a film stack with a nano-impurity profile formation in accordance with one embodiment of the present invention.

FIG. 5 is a flow chart showing a method for forming an epitaxial film or layer with a nano-impurity profile in accordance with one embodiment of the present invention.

FIG. 6 is a block diagram of a resulting nano-boron impurity profile in accordance with one embodiment of the present invention.

FIG. 7 is a flow chart showing a method for forming an epitaxial film or layer with a nano-impurity profile in accordance with one embodiment of the present invention.

FIG. 8 is a graph illustrating pulsing during formation of ultranarrow profiles in accordance with one embodiment of the present invention.

FIG. 9 is a graph illustrating pulsing during formation of ultranarrow profiles in accordance with another embodiment of the present invention.

### DETAILED DESCRIPTION OF THE INVENTION

The present invention relates to semiconductor device fabrication, and more particularly to a method and system for forming high-quality epitaxial films. The following description is presented to enable one of ordinary skill in the art to make and use the invention, and is provided in the context of a patent application and its requirements. Various modifications to the disclosed embodiments and the generic principles and features described herein will be readily apparent to those skilled in the art. Thus, the present invention is not intended to be limited to the embodiments shown, but is to be accorded the widest scope consistent with the principles and features described herein.

A method and system in accordance with embodiments of the present invention for forming high-quality epitaxial films are disclosed. One method embodiment includes cleaning a substrate and reducing adsorbed moisture on the substrate in a low-temperature, low-oxygen atmosphere. Such an embodiment also includes prebaking the substrate to remove native oxide and growing an epitaxial layer doped with an impurity, wherein the impurity has a nano-impurity profile. As a result, high-quality epitaxial layers are formed having ultra thin, nano-impurity profiles.

Although embodiments of the present invention disclosed herein are described in the context of epitaxial films with very thin, nano boron impurity profiles, various embodiments may apply to epitaxial films with very thin, nano-impurity profiles of other p-type or n-type impurities (e.g., phosphorous, arsenic, antimony, etc.), and still remain within the spirit and scope of the present invention. In addition, the impurities are not required to be of either p- or n-type, but might be of the same group in the periodic table. An example would be to add carbon to the silicon germanium matrix for the purpose of strain engineering or dopant diffusion engineering, without altering the conductivity type of the layer.

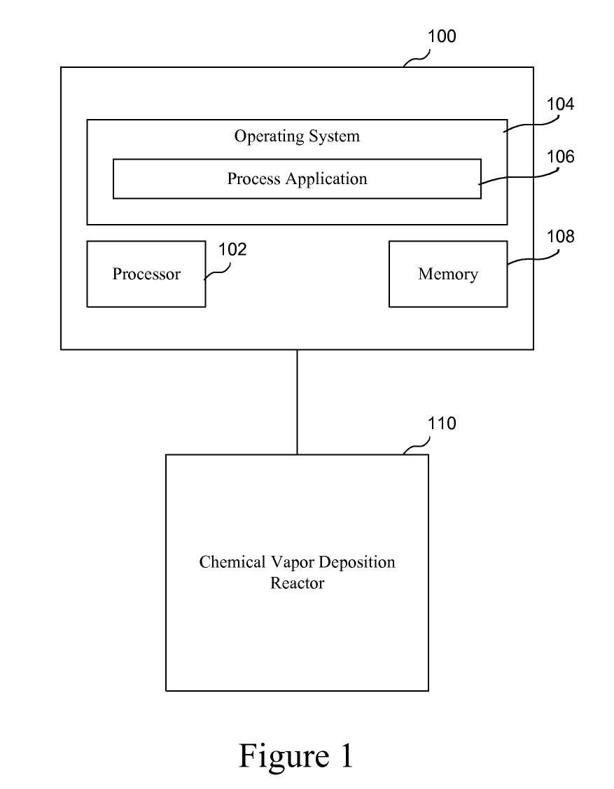

FIG. 1 is a block diagram of a computer system 100 that may be used with a chemical vapor deposition reactor in accordance with one embodiment of the present invention. As FIG. 1 shows, the computer system 100 includes a processor 102, an operating system 104, a process application 106, and a memory 108. The process application 106 may be stored with the operating system 104, on the memory 108 or on any other suitable storage location or computer-readable medium. In operation, the computer system 100 controls one or more aspects of the chemical vapor deposition reactor 110 in order to process semiconductor substrates. The process application 106 provides instructions that enable the processor 102 to perform the functions described herein.

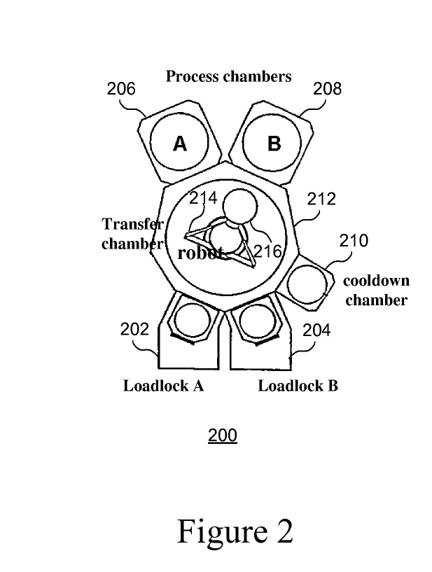

FIG. 2 is a top-view block diagram of a low-pressure chemical vapor deposition (LPCVD) reactor 200, which may be used to implement the chemical vapor deposition reactor 110 of FIG. 1, in accordance with one embodiment of the present invention. As FIG. 2 shows, the LPCVD reactor 200 includes load lock chambers 202 and 204, process chambers 206 and 208, a cool-down chamber 210, a transfer chamber 212, and a robot 214. In operation, an operator places a substrate 216 into one of the load lock chambers 202 or 204 where nitrogen (N) may be introduced to remove moisture or another pump process may be introduced to remove moisture. The robot 214 transfers the substrate 216 from one chamber to another for various processing, as described in more detail below.

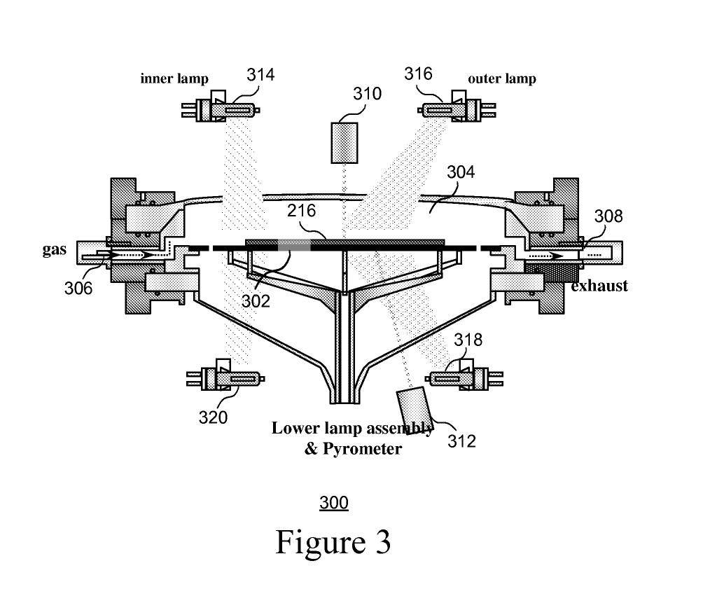

FIG. 3 is a side-view block diagram of a process chamber 300, which may be used to implement one of the process chambers 206 or 208 of FIG. 2, in accordance with one embodiment of the present invention. As FIG. 3 shows, the process chamber 300 includes a chuck 302 that supports the substrate 216 in an atmosphere 304. The process chamber 300 also includes an inlet 306 for receiving one or more gases that contribute to the atmosphere 304, and includes an outlet 308 for releasing gas from the process chamber 300. The process chamber 300 also includes pyrometers 310 and 312 and heating elements or lamps 314, 316, 318, and 320.

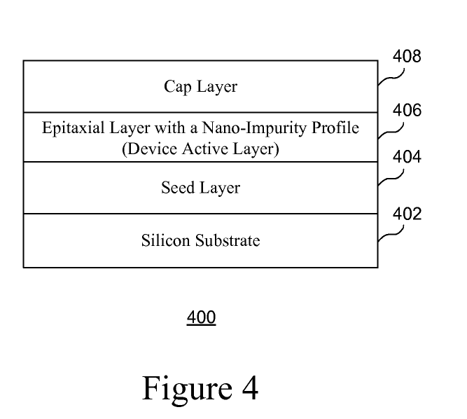

FIG. 4 is a cross-section diagram of a film stack 400 with a nano-impurity profile formation in accordance with one embodiment of the present invention. As FIG. 4 shows, the film stack 400 includes a silicon substrate 402. In other embodiments, the silicon substrate 402 may be other single crystal materials such as silicon germanium (SiGe), silicon germanium carbon (SiGeC), and/or germanium (Ge). The silicon substrate 402 may also be gallium arsenide (GaAs), indium phosphide (InP), and/or other group III/V and/or II/VI films, respectively. The film stack 400 also includes a seed layer 404. In specific embodiments, the seed layer 402 may be Si, Ge, SiGe, SiGeC, and/or SiC. The seed layer 402 may also be GaAs, InP, and/or other group III/V and/or II/VI films, respectively.

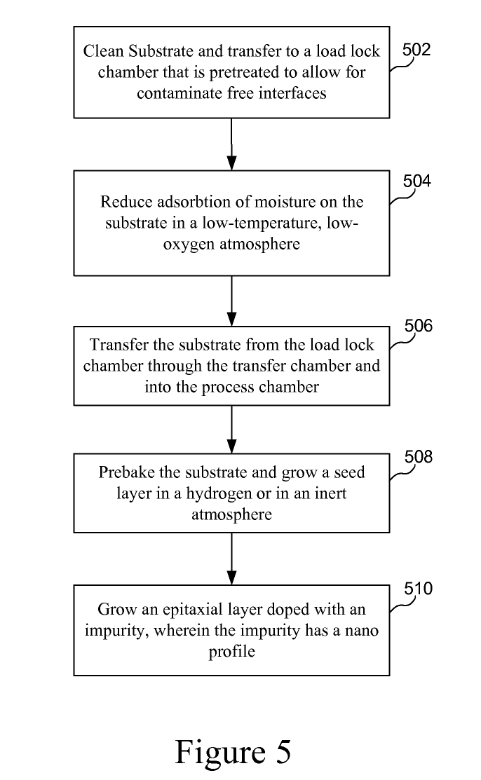

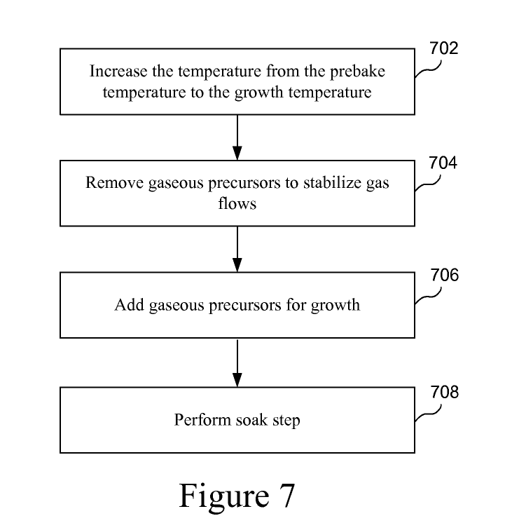

The film stack 400 also includes an epitaxial layer with a nano-impurity profile 406. In particular embodiments, the epitaxial layer may be Si, Ge, SiGe, SiGeC, and/or SiC, and the nano-impurity profile may be a nano-boron layer. In another specific embodiment, the nano-impurity profile may be a hydrogen bubble formation (very high stress) formed by implantation and/or diffusion of ionized hydrogen through the cap layer 408 and into a boron (B)-doped region. In one embodiment, the film stack 400 with the nano-impurity profile may be formed by the process flows described below in FIGS. 5 and 7, and may be carried out for GaAs, InP, and/or other group III/V and/or II/VI films, respectively.

The film stack 400 also includes a cap layer 408. In particular embodiments, the cap layer 408 may be Si, Ge, SiGe, SiGeC, SiC, Ge, GeC, and/or other group IV films. The cap layer 408 may also be GaAs, InP, and/or other group III/V and/or II/VI films, respectively. In particular embodiments, any combination of the above-mentioned film types may be used within a single layer 402-408. Also, the combinations of film types may be the same or different among the layers 402-408.

In one embodiment, the location of the impurity profile (e.g., here, at the epitaxial layer 406) is where carriers propagate through the film stack 400. As such, the epitaxial layer 406 may be referred to as the device active layer. The quantity and type of impurity affects the mobility and resistivity, as well of carrier type (e.g., holes added into silicon in the case of boron; electrons added into silicon in the case of phosphorous or arsenic).

FIG. 5 is a flow chart showing a method for forming an epitaxial film or layer with a nano-impurity profile in accordance with one embodiment of the present invention. Referring to both FIGS. 2 and 3 together, the process begins in step 502 where the substrate 216 is cleaned. In one embodiment, the substrate 216 is etched in hydrofluoric (HF) acid (HF-last cleaned), rinsed by deionized (DI) water, and dried with isopropyl alcohol (IPA).

After the substrate 216 is cleaned, it is transferred to a vacuum or load lock chamber (e.g., load lock chamber 202). In one embodiment, the load lock chamber 202 contains components conditioned or pretreated to allow for contaminate free interfaces. Embodiments that allow for contaminate free interfaces are described in one or both U.S. Pat. No. 7,044,147, issued on May 16, 2006, entitled “System, Apparatus and Method for Contaminant Reduction in Semiconductor Device Fabrication Equipment Components,” and U.S. Pat. No. 7,080,440, issued on Jul. 25, 2006, entitled “Very Low Moisture O-Ring and Method for Preparing the Same,” both of which are assigned to Atmel Corporation and are herein incorporated by reference. In one embodiment, the substrate 216 may be transferred using a standardized mechanical interface (SMIF) pod or other suitable device that can further reduce the adsorption of moisture.

Next, in step 504, the substrate adsorbtion of moisture on the substrate 216 is reduced in a low-temperature, low-oxygen atmosphere. In one embodiment, adsorbtion is reduced by repeated nitrogen (N2) cycle purging between 100 Torr and 1 mTorr, in a very short period of time (e.g., less than one or two minutes). Repeated nitrogen pumping and purging from high pressure to very low pressures removes adsorbed moisture (e.g., high pressure is 60 Torr up to atmospheric; low pressure is 1 mTorr to 10 Torr). In one embodiment, the pressure differential between high and low pressure is no less than 5 Torr, but may be lower if there are pumping limitations.

Next, in step 506, robot 214 transfers the substrate 216 from the load lock chamber 202 through the transfer chamber 212, and into the process chamber 206.

Next, in step 508, the substrate 216 is prebaked. Following the prebake, a seed layer is grown in a hydrogen (H2) or in an inert atmosphere such as helium (He). The inert atmosphere (e.g., He) enables growth at much lower temperatures and/or enhanced growth rates over that offered by the hydrogen atmosphere.

The prebake process removes surface native oxide and contaminants. In one embodiment, the prebake may be performed in a hydrogen atmosphere with the substrate 216 at predefined temperatures (e.g., from as low as 550° C. up to 1100° C.). In some processes, temperatures greater than 950° C. may be desired. In one embodiment, the prebake may be performed in an inert atmosphere such as helium or argon. Any inert will work, such as neon (Ne), argon (Ar), etc., (any of the “monatomics”). One skilled in the art will recognize that this might be advantageous to inhibit the surface passivating effect of hydrogen and allow for better adsorption of growth precursors to the substrate surface. Also, a blend of hydrogen with an inert will allow tailoring of this effect. The benefit of hydrogen is to more effectively reduce the native oxide at the surface.

Next, in step 510, an epitaxial layer doped with an impurity is grown, wherein the impurity has a nano-impurity profile. In one embodiment, the epitaxial layer may be grown in an H2 atmosphere or in an inert atmosphere (e.g., He) with gaseous precursors listed below.

In one embodiment, the atmosphere in the process chamber 206 contains a predefined level of oxygen. In one embodiment, the predefined level is very low such that oxygen measured by secondary ion mass spectrometry (SIMS) is below detection (e.g., <3E17 atoms/cc). Containing very low oxygen maintains a very clean interface between the substrate 216 and the epitaxial layer being grown. As such, extremely low amounts of oxygen are incorporated within the epitaxial layer during growth. Low oxygen results in higher epitaxial film quality, because there is less oxygen in the atmosphere that might interfere with hole mobility in p-type (or boron doped regions). Low oxygen also results in stable electrical qualities of the film and stable dopant diffusion properties. In one embodiment, low oxygen also results in more stable thermal control in high volume manufacturing conditions. More stable thermal conditions result in stable processing, especially since no change to gas flows are required to compensate for thermal changes. The reason for a more stable thermal control is that elevated oxygen and/or moisture results in hazing of the quartz reactor, which alters the transfer of infrared energy from the lamps to the substrate surface, where epitaxial film/layer growth takes place.

In particular embodiments, the prebaking and growth of the epitaxial layer or film (steps 508 and 510) may be carried out using any combination of the following gaseous precursors. If a silicon (Si) film is desired, any combination of silane (SiH4), hydrogen (H2), and/or diborane (B2H6) as the boron source may be used as gaseous precursors. If a germanium (Ge) film is desired, any combination of germane (GeH4), and/or H2 may be used as gaseous precursors. If a germanium-carbon (GeC) film is desired, any combination of GeH4, methyl silane (CH3SiH3), and/or H2 may be used as gaseous precursors. If a silicon-germanium (SiGe) film is desired, any combination of SiH4, H2, GeH4, and/or diborane (B2H6) may be used as gaseous precursors. If a silicon-germanium-carbon (SiGeC) film is desired, any combination of SiH4, H2, GeH4, CH3SiH3, and/or B2H6 may be used as gaseous precursors. If a silicon-carbon SiC film is desired, any combination of SiH4, H2, and/or CH3SiH3 may be used as gaseous precursors.

With regard to temperatures, in an H2 atmosphere, the processing temperatures may be in a predefined range. In particular embodiments, the predefined range is a low temperature range. For example, in a specific embodiment, the processing temperatures may range from a low of 500° C. to a high of 1100° C. As mentioned above, the initial prebake and seed layer growth may take place anywhere between 500° C. and 1100° C. In a specific embodiment, an epitaxial film with a nano-boron profile growth may take place in a predefined range (e.g., between 500° C. and 650° C.). An epitaxial cap layer may be grown at predefined temperatures (e.g., between 500° C. and 850° C.). A seed layer, epitaxial film with boron, and/or the cap layer may be constructed of Si, Ge, SiGe, SiGeC, or SiC, or any combination thereof.

In a helium atmosphere (or in any other inert atmosphere such as argon, neon, etc.), the processing temperatures may be predefined (e.g., range from a low of 400° C. to a high of 1100° C.). Because an inert gas does not passivate the surface, initiation of growth may be performed at much lower temperatures. The initial prebake and seed layer growth may be predefined (e.g., may take place anywhere between 500° C. and 1100° C.). In a specific embodiment, an epitaxial film with nano-boron profile growth takes place in a predefined range (e.g., between 500° C. and 650° C.). An epitaxial cap layer is grown at predefined temperatures (e.g., between 500° C. and 850° C.). A seed layer, epitaxial film with boron, and/or the cap layer may be constructed of Si, Ge, SiGe, SiGeC, or SiC, or any combination thereof.

In particular embodiments, the process gas flows are generally in the following (broad) range of mass flows. However, the process gas flows are not limited to these flow rates. In one embodiment, the flow rate for SiH4 may be 1 standard cubic centimeter per minute (sccm) to 300 sccm. In one embodiment, the flow rate for GeH4 may be 1 sccm to 500 sccm. In one embodiment, the flow rate for H2 or an inert gas such as helium (He) may be 1 sccm to 50 standard liters per minute (slpm). Note that H2 and He gases are “carrier gases” and may also be eliminated from the process if so desired (e.g., to increase growth rates). In one embodiment, the flow rate for CH3SiH3 may be 1 sccm to 500 sccm.

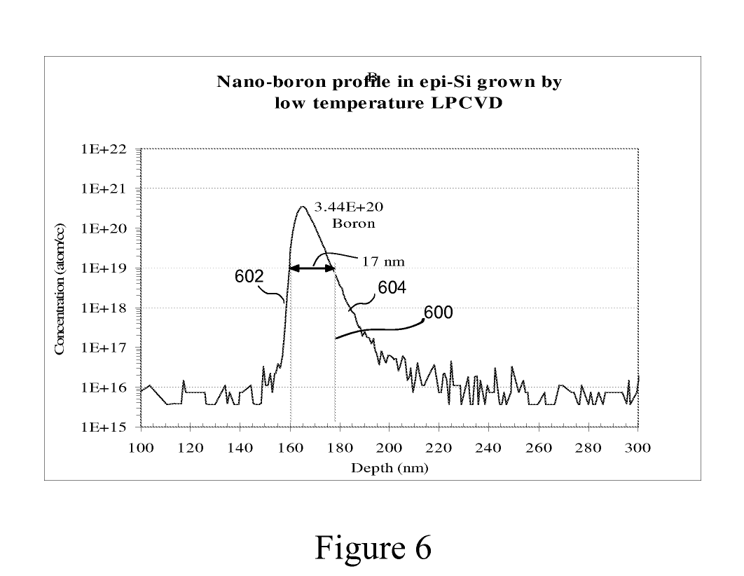

FIG. 6 is a block diagram of a resulting nano-boron impurity profile 600 in accordance with one embodiment of the present invention. As FIG. 6 shows, the nano-boron profile has a front side 602, a back side 604, width of 17 nm (170 angstroms) as measured at 1E19 at/cm³. The width of a nano-boron profile may vary and is typically measured at 1E19 atoms/cm³ as determined by secondary ion mass spectrometry (SIMS) by either an oxygen and/or cesium beam. The particular profile shown in FIG. 6 may be utilized for H2 bubble layer formation for cleaving of silicon to fabricate SOI substrates. Although FIG. 6 shows a nano-boron impurity profile, various embodiments of the present invention may apply to epitaxial films with very thin, nano-impurity profiles of other impurities (e.g., phosphorous, arsenic, antimony, etc.), and still remain within the spirit and scope of the present invention.

The following description details several embodiments of step 510 above and how these embodiments may be used to tailor the shape of a given nano-impurity profile (e.g., changing the slope of the front side 602, back side 604, or changing the widths of the nano-impurity profile).

FIG. 7 is a flow chart showing a method for forming an epitaxial film or layer with a nano-impurity profile in accordance with one embodiment of the present invention. The process begins in step 702 where the temperature of the process chamber 206 is ramped up from a predefined prebake temperature (e.g., from 550° C. to 1100° C.) to the predefined first growth temperature (e.g., 550° C. to 625° C.). The growth temperature may be predefined (e.g., 550° C. to 625° C.) in H2. However, in certain inert gases such as He, the growth temperature can be much lower (as low as 400° C.).

In some embodiments, it may be desirable to alternate between H2 and He during the growth stage. If the temperature remains constant, using He may increase the growth rate, while using H2 may decrease the growth rate. Using H2 may result in a narrower profile due to the slower growth rate. However, for layers that do not require as narrow profiles, He may be used to increase the growth rate to compensate for lost time due to the slower growth rates when H2 is used. In one embodiment, a combination of H2 and He may be used for a balance between growth rate and profile width.

Next, in step 704, the gaseous precursors are removed from the process chamber 206 to stabilize gas flows. In one embodiment, following the prebake and seed layer growth, gases are diverted to an outlet or vent (away from the reactor) in order to stabilize the mass flow controllers (MFCs). This allows the MFCs to reach steady state prior to commencing the growth process. In particular embodiments, hydrogen is typically not diverted but instead remains flowing to the reactor at all times.

Next, in step 706, the gaseous precursors are added to the reactor for film growth. Gaseous precursors such as SiH4, GeH4, and/or CH3SiH3 may be diverted to the process chamber 206 before B2H6 to begin film growth. This allows for a more abrupt beginning of the boron profile. In particular embodiments, the SiH4:B2H6 ratio may be between 1:1 and 5:1, where the H2 flows are between 5 slpm and 30 slpm. The overall growth rate may be between 1 and 5 angstroms/minute.

Next, in step 708, a soak step is performed on the surface of the substrate 216. In particular embodiments, a soak step is performed where the dopant gas such as B2H6 is introduced alone, without the presence of a growth species such as SiH4. This allows for high coverage of the substrate surface with Boron. A soak step is tailored experimentally in order to avoid too high a level of boron.

In one embodiment, several soak steps may be one means of achieving supersaturated levels of boron incorporation (i.e., ≧1E20 at/cc). Soak steps enable greater peak concentrations of boron (or another dopant).

In one embodiment, H2, He, SiH4, GeH4, and/or CH3SiH3 may be momentarily turned off to allow a B2H6 soak step to saturate the substrate surface with B2Hx species. Then the gases are redirected to the reactor to continue with film growth. This process may be repeated to achieve the desired profile. This is not required, however, to achieve the narrowest profiles, and may not be desirable if the goal is to achieve an extremely narrow profile such as the one illustrated in FIG. 6.

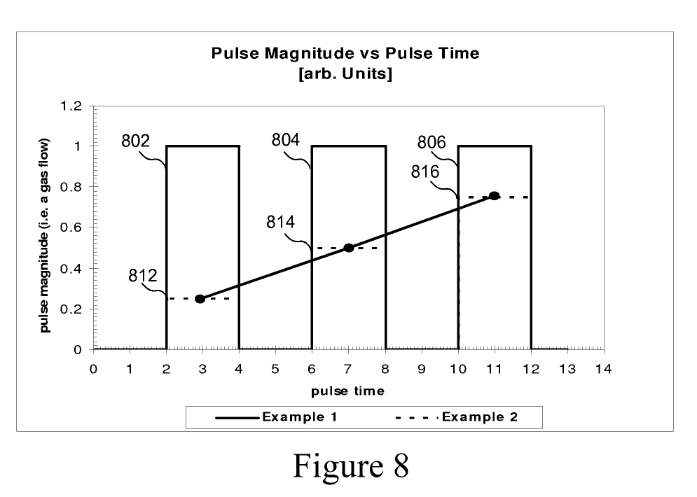

FIG. 8 is a graph illustrating pulsing during formation of ultranarrow profiles in accordance with one embodiment of the present invention. As FIG. 8 shows, B2H6 may be “pulsed” for short durations during this step. During this step, there is the “pulse” time and there is the “off” time. Additionally, the growth precursors may also be pulsed to facilitate the formation of ultranarrow profiles. In one embodiment, the pulses may have the same magnitude (gas flow rate) 802, 804, and 806. In another embodiment, each successive pulse may have a larger magnitude. For example, a first pulse may have a particular magnitude 812, a second pulse may have a larger magnitude 814, and a third pulse may have a larger magnitude 816. Changing the magnitude of successive pulses tailors the nano-impurity profile by changing amount of the impurity added during each pulse. This is because the amount of impurity, which is adsorbed onto the substrate surface will be strongly dependent on pulse magnitude and pulse duration (assuming temperature and pressure are held constant).

In one embodiment, the pulse may be structured such that the total time between pulses is greater than the chamber residence time. The chamber residence time (τ) is a function of pressure (P), chamber volume (V), and total gas load (Q) such that:

τ=PV/Q therefore, the time (t) between pulses should be such that t>τ. This allows the reactor to be cleared of precursor and for the growth process to be extinguished before introducing the next pulse of gas. This facilitates a monolayer by monolayer growth of film.

Depending on the application and also on the dopant profile needed, the reactor residence time, τ, may be tailored. Some processes may desire the shortest residence time possible. Since chamber volume is a constant, this means that P and Q may be tailored. A low P and a high Q may achieve a reduced residence time. However, this may also be balanced with the film growth rate. Increasing the hydrogen flow between pulses of precursor is often an optimal choice to attain a low τ. During the off time, H may be increased to increase Q, which lowers the reactor residence time. This is beneficial when a sooner pulse is desired.

In one embodiment, during the off time between pulses, the gaseous precursors are cleared. Clearing out the gaseous precursors improves film quality (e.g., fewer lattice defects) and improves growth with more control. If the gaseous precursors are not cleared out, some control over the growth is lost.

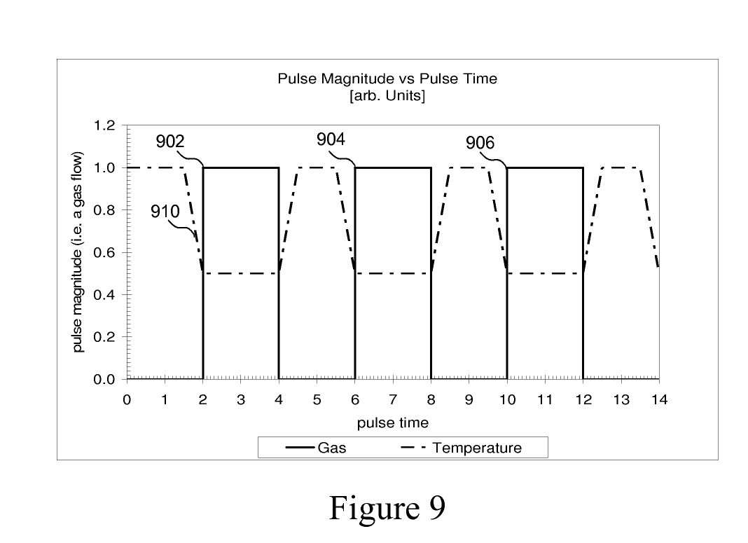

FIG. 9 is a graph illustrating pulsing during formation of ultranarrow profiles in accordance with another embodiment of the present invention. As FIG. 9 shows, the pulses may have the same magnitude 902, 904, and 906 while the temperature 910 of the atmosphere is pulsed or cycled, also referred to as thermal pulsing. In particular embodiments, thermal pulsing may occur with or without magnitude (gas flow) pulsing. In one embodiment, when the temperature is reduced when the magnitude is pulsed, thermal pulsing reduces growth rate and/or alters surface adsorption of dopant (precursor), which tailors dopant profiles, especially ultranarrow, supersaturated profiles.

In one embodiment, pressure may be pulsed, where the pressure may be modulated with a throttle value to open or close the outlet to decrease or increase pressure. In one embodiment, any combination of the above-describe variables (e.g., magnitude, temperature, pressure, etc.) may be pulsed to control growth and tailor the nano-impurity profile.

In one embodiment, following the first growth, in which a nano-boron profile is formed, the gases are once again diverted (away from the reactor) to clear the reactor of gaseous precursors before commencing the cap layer growth. This allows for an abrupt ending of the nano-boron profile formation. Cap layer growth may be optional in some scenarios but may be desired for strain layers. In one embodiment, the cap layer may be an undoped epitaxial layer and may consist of Si, Ge, SiGe, SiGeC, or SiC or any combination thereof. The cap layer may also be doped with any p-type or n-type dopant.

The embodiments described above enable precise tailoring of nano-impurity profiles in epitaxial layers. Different applications require different nano-impurity profiles. Because the embodiments described herein enable thinner nano-impurity profiles, resulting nano-impurity profiles may have more applications. The formation of ultra-thin impurity profiles has applications in a number of technologies. In one application, formation of ultra-thin impurity profiles may be utilized to form ultrashallow junctions. In another application, formation of ultra-thin impurity profiles may be utilized to form ultranarrow base layers for bipolar junction transistors (BJT) and heterojunction bipolar transistors (HBT). In another application, formation of ultra-thin impurity profiles may be utilized to form hydrogen (H2) bubble layer formation for the cleaving of silicon. In another application, formation of ultra-thin impurity profiles may be utilized to form etch-stops for standard semiconductor manufacturing and for bond and etchback in silicon-on-insulator (SOI) processing. In one embodiment, etch-stops result in very uniform layers, because the etch is “stopped” over a very short distance due to the extremely narrow profile.

According to the system and method disclosed herein, the present invention provides numerous benefits. For example, embodiments of the present invention provide high-quality epitaxial layers which are formed having ultra thin, nano-impurity profiles. Embodiments of the present invention also enable applications such as ultrashallow junctions, ultranarrow base layers for bipolar junction transistors and heterojunction bipolar transistors, hydrogen bubble layer formation for cleaving of silicon, and etch-stops for standard semiconductor manufacturing and for bond and etchback in silicon-on-insulator processing.

The present invention has been described in accordance with the embodiments shown. One of ordinary skill in the art will readily recognize that there could be variations to the embodiments, and that any variations would be within the spirit and scope of the present invention. For example, embodiments of the present invention may be implemented using hardware, software, a computer-readable medium containing program instructions, or a combination thereof. Software written according to the present invention or results of the present invention may be stored in some form of computer-readable medium such as memory, hard drive, CD-ROM, DVD, or other media for subsequent purposes such as being executed or processed by a processor, being displayed to a user, etc. Also, software written according to the present invention or results of the present invention may be transmitted in a signal over a network. In some embodiments, a computer-readable medium may include a computer-readable signal that may be transmitted over a network. Accordingly, many modifications may be made by one of ordinary skill in the art without departing from the spirit and scope of the appended claims.

What is claimed is:

1. A method comprising:
cleaning a substrate;
reducing adsorbed moisture on the substrate in a predefined temperature and predefined oxygen level atmosphere;
removing native oxide from the substrate;
prebaking the substrate; and
growing an epitaxial layer doped with an impurity, wherein the impurity has a nano-impurity profile.

2. The method of claim 1 wherein the prebaking is performed in an inert atmosphere.

3. The method of claim 1 wherein the prebaking is performed in a helium atmosphere.

4. The method of claim 1 wherein the prebaking is performed in an atmosphere that is less than 500 degrees Celsius.

5. The method of claim 1 wherein the impurity is boron.

6. The method of claim 1 wherein the growing comprises adding one or more gaseous precursors to the atmosphere in pulses.

7. The method of claim 1 wherein
the growing comprises adding one or more gaseous precursors to the atmosphere in pulses,
the one or more gaseous precursors are added to the atmosphere during a pulse time and are not added during an off time,
the off time is greater than a chamber residence time, and
the chamber residence time is a measure of how long the one or more gaseous precursors linger after being introduced to the atmosphere.

8. The method of claim 1 wherein the growing comprises:
adding one or more gaseous precursors to the atmosphere in pulses, wherein the one or more gaseous precursors are added to the atmosphere during a pulse time, and are not added during an off time; and
increasing gas flow with each successive pulse.

9. The method of claim 1 wherein the growing comprises:
adding one or more gaseous precursors to the atmosphere in pulses, wherein the one or more gaseous precursors are added to the atmosphere during a pulse time, and are not added during an off time;
increasing temperature of the atmosphere during each off time; and
decreasing the temperature of the atmosphere during each pulse time.

10. The method of claim 1 wherein the growing comprises changing temperature of the atmosphere in pulses.

11. The method of claim 1 wherein the growing comprises changing pressure of the atmosphere in pulses.

12. The method of claim 1 wherein the epitaxial layer is utilized to form ultrashallow junctions.

13. The method of claim 1 wherein the epitaxial layer is utilized to form ultranarrow base layers for bipolar junction transistors and heterojunction bipolar transistors.

14. The method of claim 1 wherein the epitaxial layer is utilized to form hydrogen bubble layers for cleaving of silicon.

15. The method of claim 1 wherein the epitaxial layer is utilized to form etch-stops for standard semiconductor manufacturing and for bond and etchback in silicon-on-insulator processing.

16. A system comprising:
a load lock chamber operable to reduce adsorbtion of moisture on the substrate in a predefined temperature and predefined oxygen level atmosphere;
a transfer chamber being coupled to the load lock chamber and operable to transfer the substrate to the process chamber;
a process chamber being coupled to the transfer chamber and operable to prebake the substrate and to grow an epitaxial layer doped with an impurity, wherein the impurity has a nano-impurity profile.

17. The system of claim 16 wherein the process chamber prebakes the substrate in an inert atmosphere.

18. The system of claim 16 wherein the process chamber grows the epitaxial layer by adding one or more gaseous precursors to the atmosphere in pulses.

19. The system of claim 16 wherein the process chamber grows the epitaxial layer by adding one or more gaseous precursors to the atmosphere in pulses, wherein
the one or more gaseous precursors are added to the atmosphere during a pulse time, and are not added during an off time,
the off time is greater than a chamber residence time, and
the chamber residence time is a measure of how long the one or more gaseous precursors linger after being introduced to the atmosphere.

20. The system of claim 16 wherein the process chamber grows the epitaxial layer by:
adding one or more gaseous precursors to the atmosphere in pulses, wherein the one or more gaseous precursors are added to the atmosphere during a pulse time and are not added during an off time; and
increasing gas flow with each successive pulse.
